(19) United States
(12) Patent Application Publication
(10) Pub. No.: US 2014/0342516 A1
(43) Pub. Date: Nov. 20, 2014

(54) METHOD OF MAKING A DYNAMIC RANDOM ACCESS MEMORY ARRAY

(71) Applicant: Fudan University, Shanghai (CN)

(72) Inventors: Wu Dongping, Shanghai (CN); Zhang Shi-Li, Stockholm (SE); Wang Pengfei, Shanghai (CN); Zhang Wei, Shanghai (CN)

(21) Appl. No.: 14/264,048

(22) Filed: Apr. 28, 2014

Related U.S. Application Data
(62) Division of application No. 13/255,503, filed on Sep. 8, 2011, now abandoned.

(30) Foreign Application Priority Data
Feb. 4, 2010 (CN) 201010105582.1

(51) Int. Cl. H01L 27/108

(52) U.S. Cl. CPC H01L 27/10864; H01L 27/1087; H01L 27/10876
USPC 438/243

(57) ABSTRACT

The present invention is related to microelectronic technologies, and discloses specifically a method of making a dynamic random access memory (DRAM) array. The DRAM array uses vertical MOS field effect transistors as array devices for the DRAM, and a buried metal silicide layer as buried bit lines for connecting multiple consecutive vertical MOS field effect transistor array devices. Each of the vertical MOS field-effect-transistor array devices includes a double gate structure with a buried layer of metal, which acts at the same time as buried word lines for the DRAM array. The DRAM array according to the present invention provides increased DRAM integration density, reduced buried bit line resistivity, and improved memory performance of the array devices.

### CROSS REFERENCE TO RELATED APPLICATION

The present application is a divisional application of U.S. patent application Ser. No. 13/255,503, filed Sep. 8, 2011, entitled “A Dynamic Random Access Memory Array and Method of Making,” which is incorporated herein by reference in its entirety.

### FIELD

The present invention belongs to the field of microelectronic technologies, and is related to the structures and fabrication methods of semiconductor memories, and more particularly to a method of making a dynamic random access memory (DRAM) array.

### BACKGROUND

Random Access Memory (RAM) is a kind of semiconductor memory that randomly reads out or writes in data at a high speed (The speed for read operations can be different from that for write operations). The advantages of RAM include high speed memory accesses and ease of read/write operations. The disadvantages include short data retention time and loss of data after power is turned off. Thus, RAM is mainly used as main memories for computers and other systems that require high-speed memory accesses. Based on the methods of operation, RAM is separated into Static Random Access Memory (SRAM) and Dynamic Random Access Memory (DRAM).

A storage unit of DRAM is typically comprised of an array device made of a metal-oxide-semiconductor field effect transistor (MOSFET) and a capacitor coupled to the MOSFET. The MOSFET is used to charge and discharge the capacitor, and the amount of charge stored on the capacitor, i.e., the level of a voltage across the capacitor, is used to represent a “1” or “0.” DRAM has relatively high integration, low energy consumption, fast read/write speed, and widespread usage. On the other hand, it has obvious shortcomings. In order to avoid gradual loss of the information stored in the storage units through capacitor leakage, the information is rewritten into the storage units every 2-4 microseconds (refresh). Without these refresh operations, the information stored will be lost. The information will also be lost when power is turned off.

With the continuing miniaturization and high-speed development of DRAM technologies and products, DRAM storage units are gradually shrinking and the corresponding technologies are becoming more and more challenging. For DRAM array devices, not only the size and area need to shrink, large on-state current and small leakage are also required. Since ordinary two-dimensional devices can no longer satisfy such requirements, three-dimensional devices such as recessed channel array transistors (RCAT) gradually find their use in advanced DRAM technologies and products. As DRAM technologies move into the sub-30 nm sector, in order to continually meet the demands of high speed and high information integrity, there is a need to use new array device structures to replace RCAT and related improvement device structures.

### SUMMARY

An objective of the present invention is to provide a new DRAM array and methods of making. The DRAM array can satisfy the requirements of large on-state current and small leakage current, and the requirements of high-speed memory accesses and high information integrity, for DRAM devices. The DRAM array according to the present invention utilizes vertical MOS field-effect-transistors as DRAM array devices, and a buried metal silicide layer as buried bit lines for connecting multiple consecutive vertical MOS field effect transistor array devices. The vertical MOS field-effect-transistor array devices include double gate structures using a buried layer of metal, which acts at the same time as buried word lines for the DRAM array. The buried metal silicide layer is a contiguous layer in a horizontal direction and is disposed in a semiconductor substrate. The semiconductor substrate can be single-crystal silicon, polysilicon or silicon-on-oxide (SIO). The metal silicide can be titanium silicide, cobalt silicide, nickel silicide, platinum silicide, or a combination of two or more thereof.

Furthermore, the present invention also provides a method of making a DRAM array. The method includes the following:
providing a semiconductor substrate doped with a first dopant type;
forming shallow trench isolation structures for the devices;
implanting ions to form doped regions of a second dopant type;
forming a first insulating dielectric layer;
etching the first insulating dielectric layer and the substrate to form opening structures;
forming an etch mask layer;
anisotropically etching the etch mask layer to expose areas of silicon for forming metal silicides;
implanting ions to form doped regions of a third dopant type;
depositing a first metal layer followed by annealing to cause the metal layer to react with the exposed areas of silicon to form metal silicide;
removing remaining metal;
forming a second insulating dielectric layer;
dry etching the second insulating dielectric layer and the remaining etch mask layer, thereby keeping only parts of the second insulating dielectric layer and the etch mask layer near bottoms of the openings;
forming a gate insulator layer;
depositing a second metal layer and performing anisotropic dry etching on the second metal layer to form metal gate electrodes;
depositing a third insulating dielectric layer, and planarizing a surface of the substrate;
removing a remaining portion of the first insulating dielectric layer to expose doped regions of a second dopant type; and
coupling capacitors to the respective doped regions of the second dopant type.

Preferably, the semiconductor substrate is single crystal silicon, polysilicon or SOI. The first insulating dielectric layer and the second insulating dielectric layer are deposited SiO₂ or Si₃N₄ film, or a multilayer structure formed using SiO₂ or Si₃N₄ and polysilicon films. The etch mask layer is comprised of SiO2, Si₃N₄, or a combination thereof.

Preferably, the first dopant type is lightly-doped P-type, the second dopant type and the third dopant type are both heavily doped N-type. Or, the first dopant type is lightly doped N-type, the second dopant type and the third dopant type are both heavily doped P-type. The doped region of the first dopant type and the doped regions of the second dopant type form P-N junction structures, and doped region of the first dopant type and the doped regions of the third dopant type form P-N junction structures.

Preferably, the first metal is titanium, cobalt, nickel, platinum or a combination two or more thereof. The metal silicides expand in different directions while being formed, connecting with each other in a horizontal direction to form a contiguous buried metal silicide layer. The buried metal silicide layer is disposed within the doped regions of the third dopant type and is used as a bit line for the DRAM array.

Preferably, the gate insulator layer is SiO₂, HfO₂, HfSiO, HfSiON, SiON, Al₂O₃ or a combination of two or more thereof. The metal gate electrodes are used to control the DRAM array devices and as buried word lines for the DRAM array. The buried word lines are perpendicular to the buried bit lines.

As an advantage of the present invention, the DRAM array provides increased DRAM integration density, reduced buried bit line resistivity, and improved memory performance of the array devices.

### BRIEF DESCRIPTION OF THE DRAWINGS

FIGS. 1b, 2b, 3b, 4b, and 5 to 12 are cross-sectional diagrams of processes for forming N-type vertical MOS field-effect-transistor DRAM array devices provided by embodiments of the present invention.

FIG. 1a is a plan view of illustrated structure in FIG. 1a.

FIG. 1c is a cross-sectional diagram taken along line “a-b” in FIG. 1a.

FIG. 2a is a plan view of illustrated structure in FIG. 2b.

FIG. 3a is a plan view of illustrated structure in FIG. 3b.

FIG. 4a is a plan view of illustrated structure in FIG. 4b.

FIG. 13 is a cross-sectional diagram of P-type vertical MOS field-effect-transistor DRAM array devices provided by the present invention.

### DETAILED DESCRIPTION OF THE EMBODIMENTS

Following is detailed description of embodiments of the present invention with reference to the drawings. In the drawings, for ease of explanation, the thickness of layers and regions are enlarged or minimized, so the sizes shown in the drawings do not represent actual sizes or their proportions. Although the drawings do not accurately reflect the actual device sizes, they still represent relative positions of regions and structures, especially above/below and neighboring relationships of the structures.

The drawings illustrate preferred embodiments of the present invention, but the illustrated embodiments are not limited by the specific shapes of the regions illustrated. Instead, the embodiments include different shapes resulted, for example, from variations in actual fabrication processes. For example, surface profiles obtained from etching usually have curving or rounding characteristics, but are instead represented by rectangular shapes. Such illustrations in the drawings are not to limit the scope of the invention. Also, in the following description, the terms “substrate” can be understood as including a semiconductor wafer in the process of fabrication, which may include other thin films formed thereon.

### Example 1

### N-Type Vertical MOS Field-Effect-Transistor DRAM Array Devices

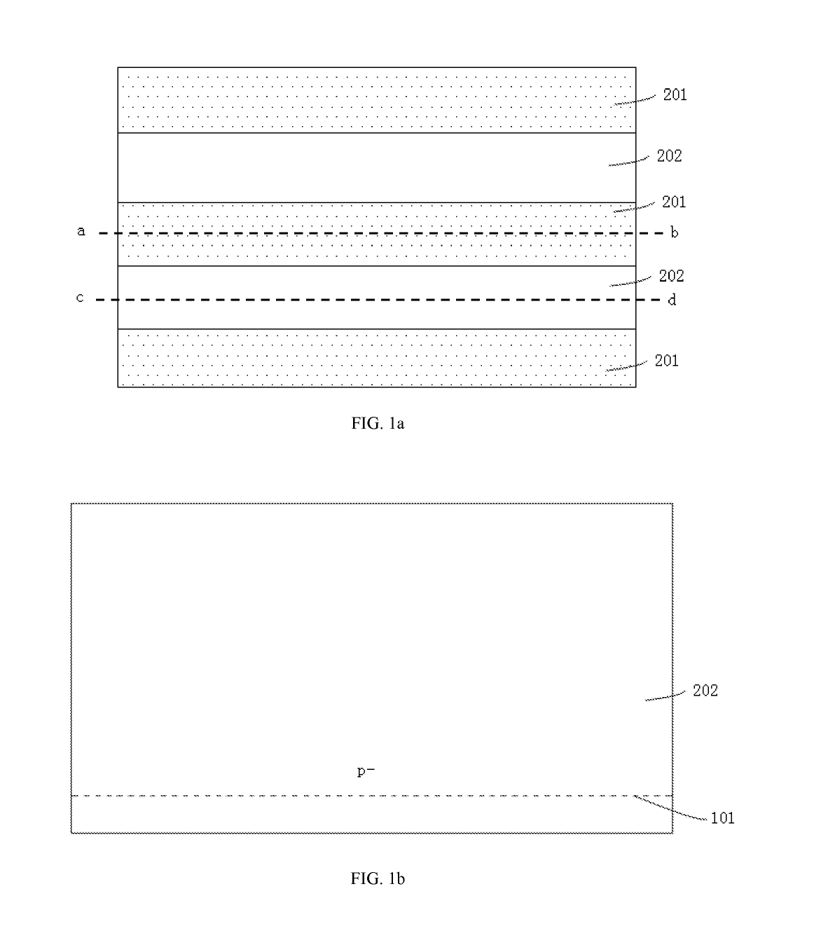

FIG. 1a is a plan view of a resulting structure of a semiconductor substrate. A P-type doped semiconductor substrate is provided and shallow trench isolation regions are formed thereon. Illustrated regions 201 are shallow trench isolation (STI) regions, and regions 202 are silicon active regions. STI regions and silicon active regions form alternating stripe structures. FIG. 1b is a cross-sectional diagram taken along dotted line “c-d” in FIG. 1a, with dotted line 101 representing a depth of the STI regions. FIG. 1c is a cross-sectional diagram taken along dotted line “a-b” in FIG. 1a.

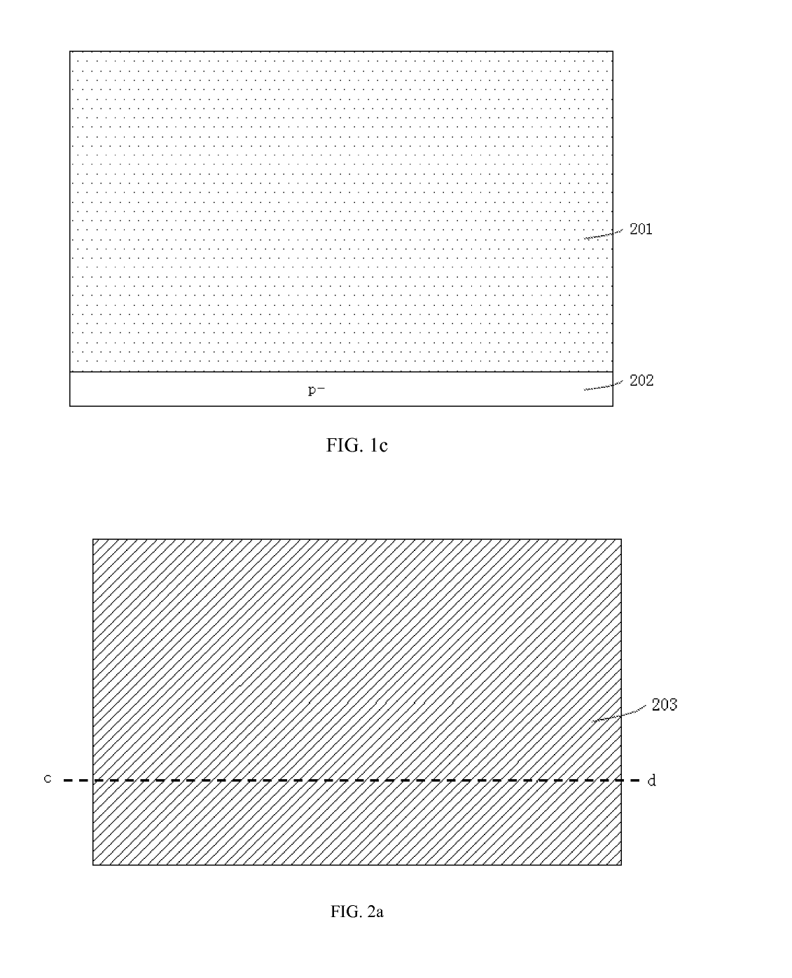

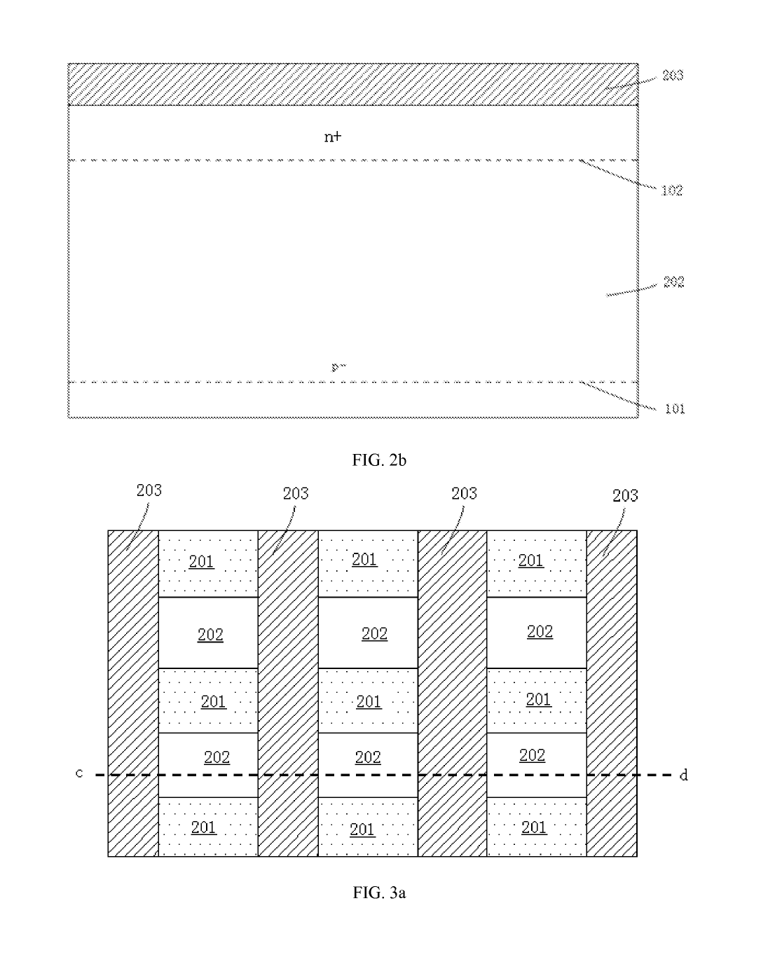

Subsequently, N-type dopants are implanted, forming first highly-doped N-type regions near a surface of the silicon substrate and P-N junctions in the P-type doped silicon substrate. Then, a thin film 203 is deposited on the silicon substrate. Thin film 203 can be SiO₂, Si₃N₄ or a multilayer structure formed using SiO₂ and/or Si₃N₄ and polysilicon. The resulting substrate structure is illustrated by the plan view in FIG. 2a. FIG. 2b is a cross-sectional diagram taken along dotted line “c-d” in FIG. 2a. Dotted line 102 in FIG. 2b represents a depth of the P-N junction.

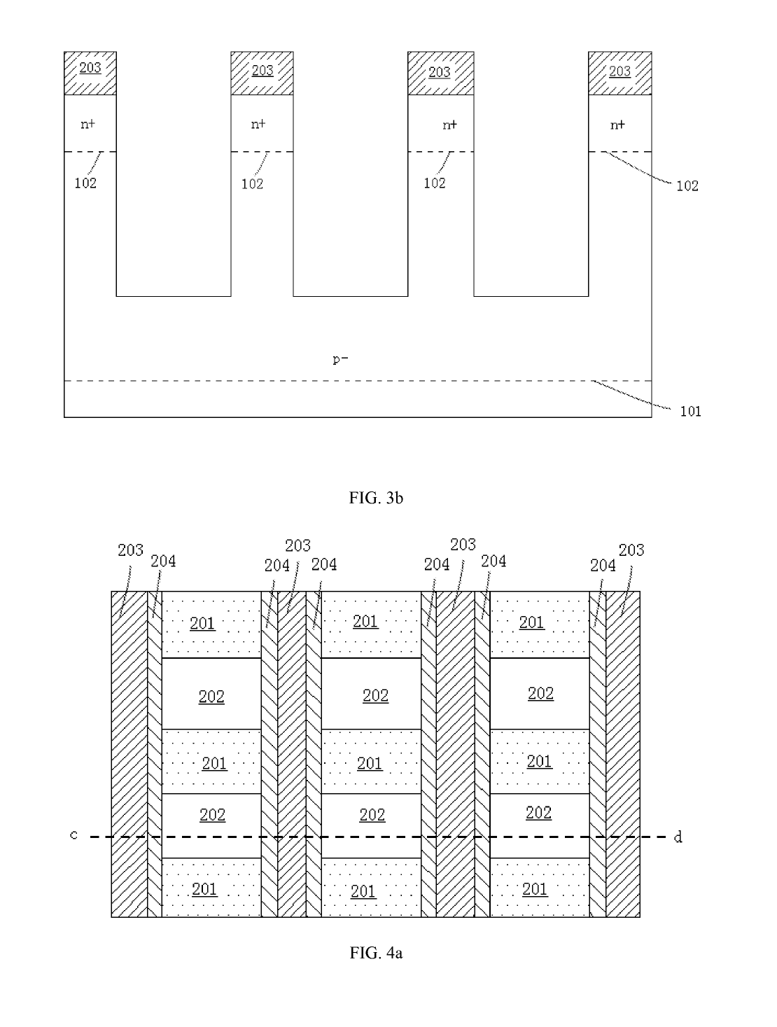

Subsequently, a photoresist layer is formed, and anisotropic etching is performed on the photoresist layer, the thin film 203 and the semiconductor substrate to form openings. The photoresist layer is then removed, resulting in the device structure illustrated by the plan view in FIG. 3a. FIG. 3b is a cross-sectional diagram taken along dotted line “c-d” in FIG. 3a.

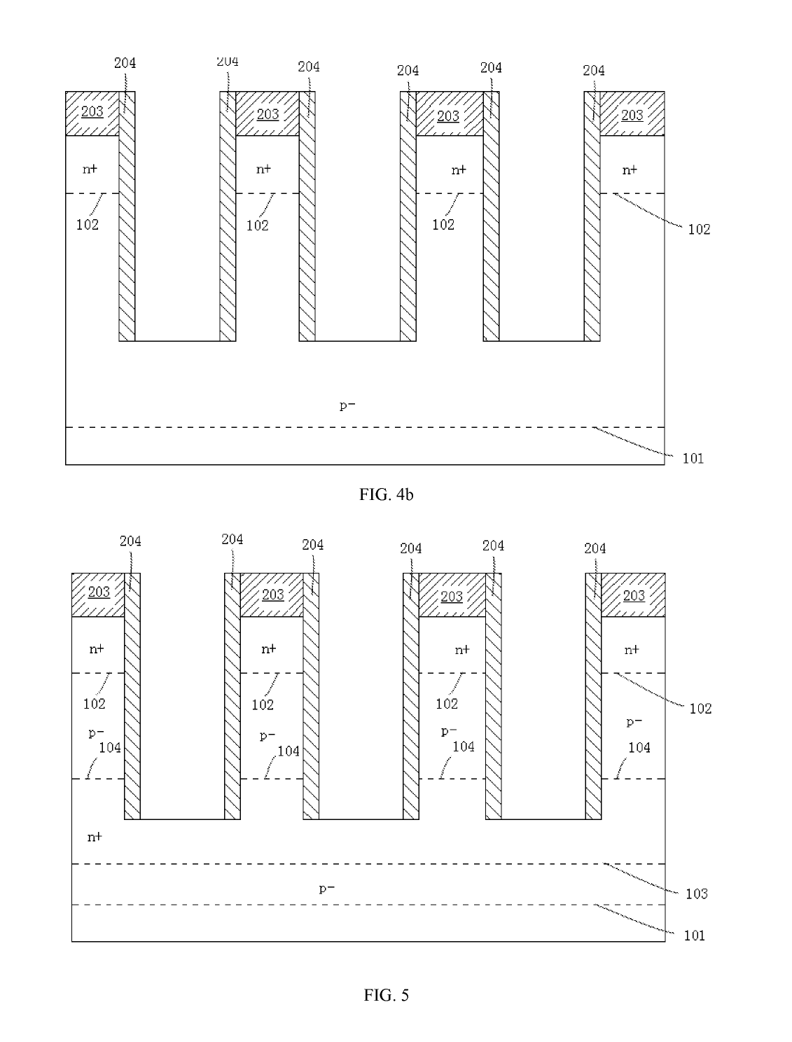

Subsequently, a thin film 204 is formed by deposition, and anisotropic etching is performed on the thin film 204 to expose areas of silicon at the bottoms of the openings for forming silicide materials, resulting in the device structure illustrated by the plan view in FIG. 4a. FIG. 4b is a cross-sectional diagram taken along dotted line “c-d” in FIG. 4a. Thin film 204 can be an insulating material made of SiO₂, Si₃N₄ or a combination thereof.

In the following fabrication processes, only cross-sectional diagrams along line “c-d” in FIG. 1 are shown, while plan views of the device structures are not shown.

As shown in FIG. 5, N-type ions are implanted into the openings, forming second highly-doped N-type region in the substrate and additional P-N junctions in the p-type doped substrate. Dotted lines 103 and 104 represent depths of the newly formed P-N junctions. An annealing step is generally performed after the N-type dopant implant to activate the N-type dopant ions. While being activated, the implanted N-type dopant ions would diffuse in all directions and form a contiguous highly-doped N-type region by joining each other in a horizontal direction. Note that the implanting of the N-type dopant ions and the subsequent annealing to activate the ions can be performed before thin film 204 is formed.

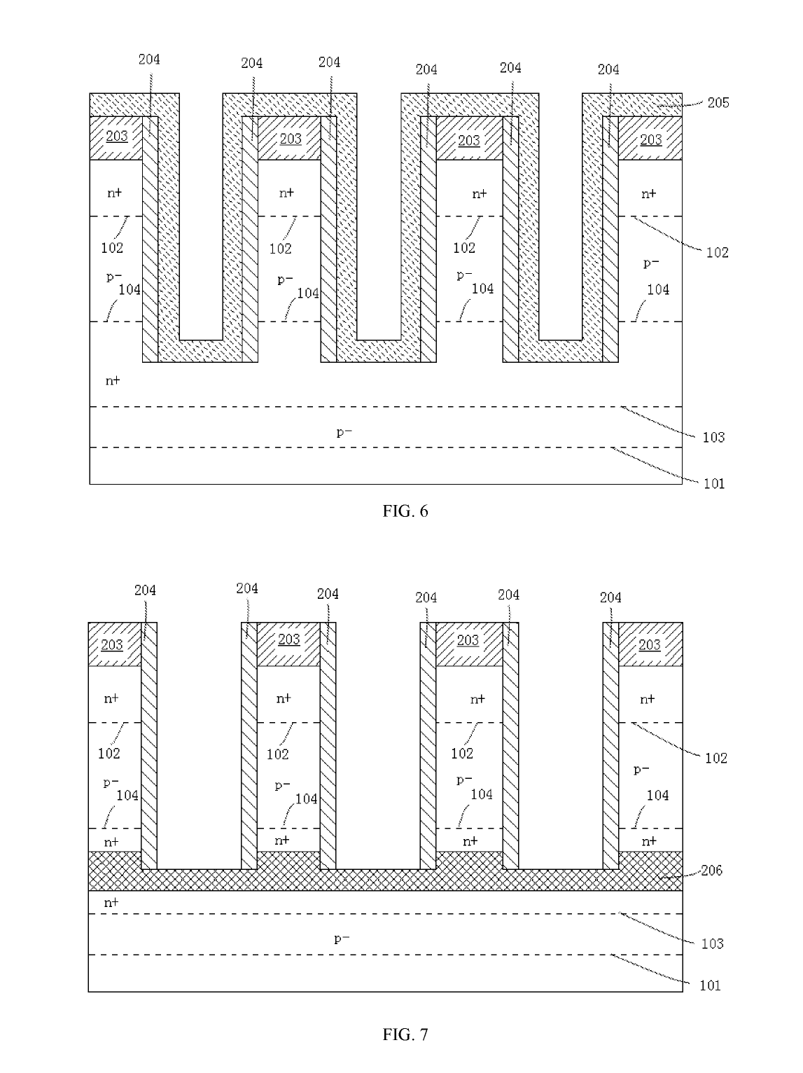

As shown in FIG. 6, a metal layer 205 is formed by deposition. The metal layer 205 can be titanium, cobalt, nickel, platinum or a combination of two or more thereof.

Afterwards, an annealing technology is used to cause the metal layer 205 to react with only the exposed areas of the silicon substrate, thereby forming a buried metal silicide layer 206 in the second highly-doped N-type region. The unreacted metal is subsequently removed, as shown in FIG. 7. The buried metal silicide layer 206 is used as a buried bit line for the DRAM array to connect multiple consecutive vertical MOS field-effect-transistor array devices. If metal silicides formed at the respective openings are sufficiently thick or the width of the silicon between the openings is sufficiently small, the metal silicides can form a contiguous metal silicide layer in the horizontal direction. The temperature for the annealing technology can be controlled at 300° C. to 900° C. During annealing, the metal react with silicon to form metal silicides but does not react or react weakly with insulator layers. Also, in order to form the contiguous metal silicide layer, the exposed silicon at the bottoms of the openings, as shown in FIG. 4b, can be isotropically etched, thereby reducing the width of the exposed silicon between the openings.

Afterwards, a layer of insulating dielectric thin film 207 is deposited. The insulating dielectric thin film 207 is preferably SiO₂. The thin film 207 and thin film 204 are dry etched to form the structure shown in FIG. 8. Note that the original thin film 203 is generally thinned during the dry etch process.

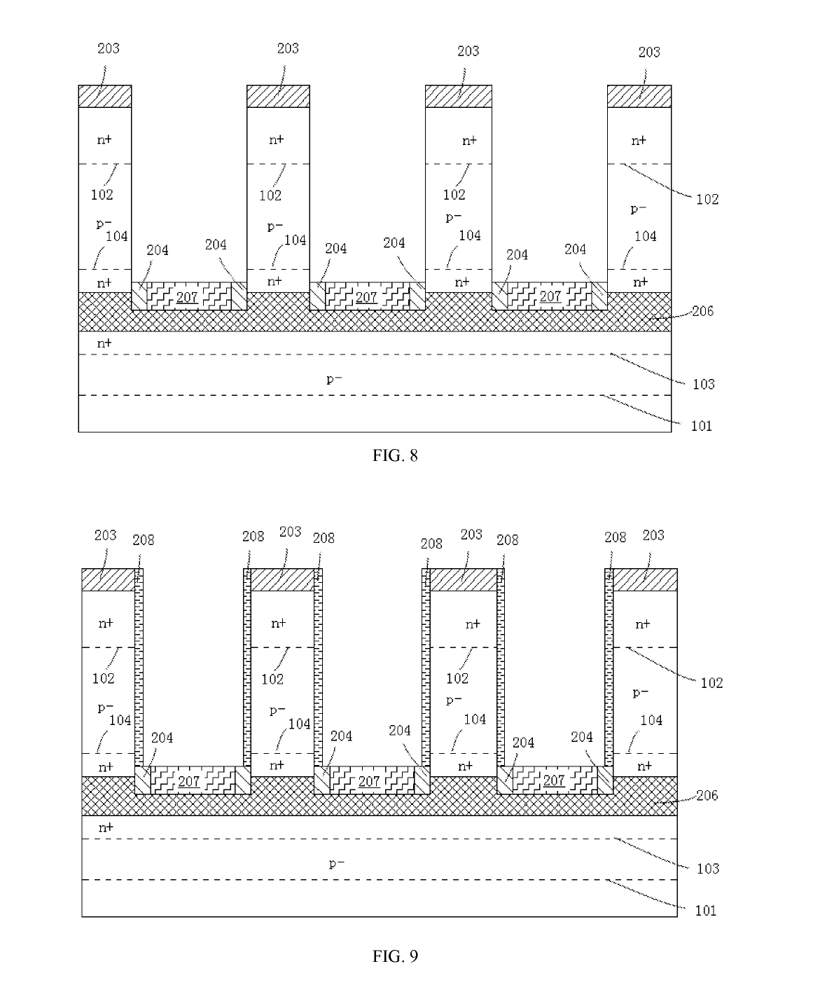

Afterwards, a gate insulator layer 208 is formed, as shown in FIG. 9. The gate insulator layer 208 can be thermally grown SiO₂ or a SiO₂ or high-k dielectric layer formed by deposition. Note that if the gate insulator layer 208 is a deposited dielectric layer, the dielectric layer would cover all exposed surfaces of the substrate.

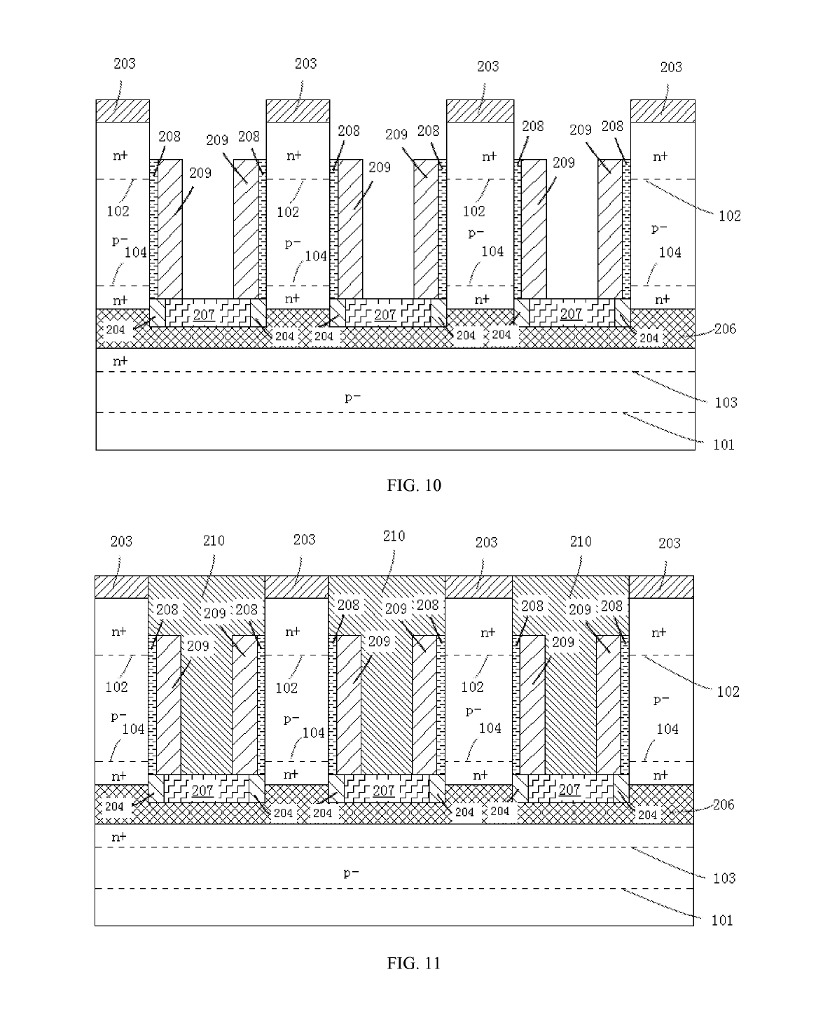

Afterwards, a metal layer 209 is formed by deposition. The metal layer 209 can be TiN, Ti, Ta, TaN or a combination of two or more thereof. Anisotropic dry etch is performed on the metal layer 209 to form the metal gate electrode structures shown in FIG. 10. As shown in FIG. 10, each vertical field-effect-transistor is controlled by two metal gate electrodes, and the metal gate electrodes form at the same time buried word lines for the DRAM array. These buried word lines are perpendicular to the buried bit line formed by the metal silicide layer 206.

Subsequently, a dielectric layer 210 filling the openings is formed. The dielectric layer 210 can be a insulating dielectric layer containing SiO₂. Then chemical mechanical polishing or etching is performed to planarize the dielectric layer 210, forming the structure shown in FIG. 11.

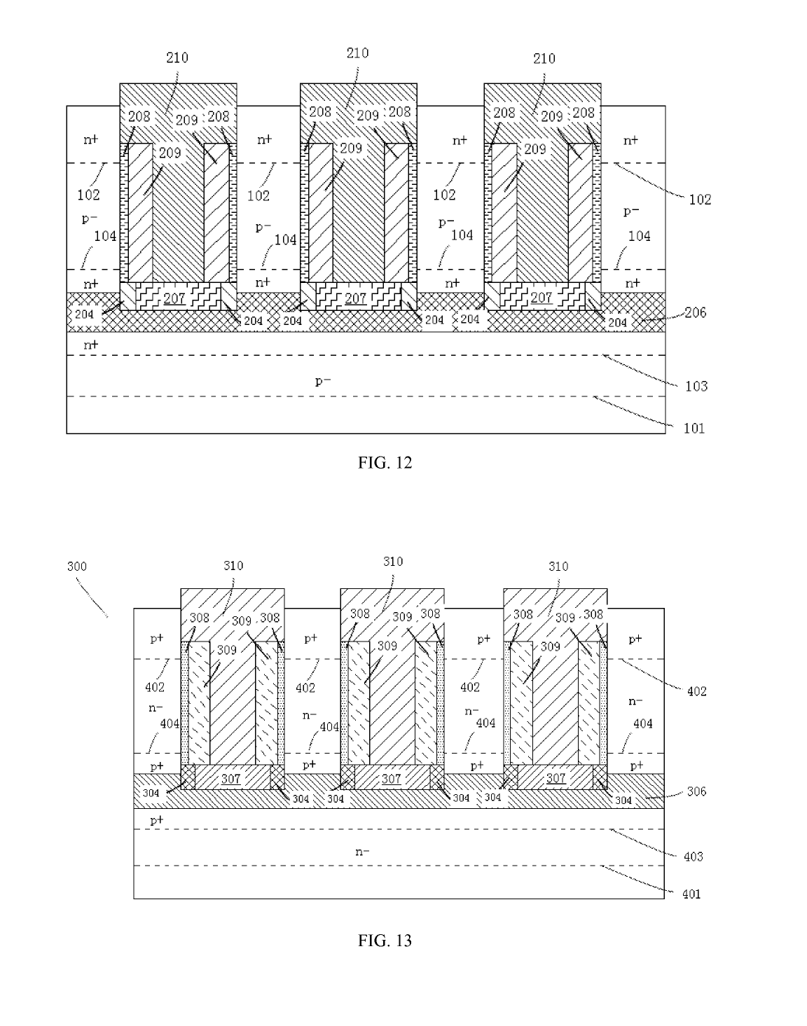

Lastly, thin film 203 is removed, as shown in FIG. 12. Thus, the vertical MOS field-effect-transistor array devices and buried word lines and bit lines connecting multiple array devices are formed.

After subsequent processes to form the capacitors (not shown) coupled to the heavily doped N-type regions in the vertical MOS field-effect-transistor array devices, the DRAM array is formed.

### Example 2

### P-Type Vertical MOS Field-Effect-Transistor DRAM Array Devices

FIG. 13 illustrates a structure of P-type vertical MOS field-effect-transistor array devices and buried word lines and a buried bit line connecting multiple array devices. The dopant types for the substrate and vertical field-effect-transistors in this example are opposite to those in Example 1, i.e., the substrate is N-type, while the vertical field-effect-transistors are P-type. As shown in FIG. 13, layer 304 is SiO₂, Si₃N₄, or an insulator material of a combination thereof. Layer 306 in FIG. 13 is a metal silicide layer, which is used as buried lines connecting multiple consecutive vertical MOS field-effect-transistor array devices. Layer 307 in FIG. 13 is a SiO₂ dielectric layer. Reference numeral 308 represents gate insulator layers, which can be thermally grown SiO₂ or a SiO₂ or high-k dielectric layer formed by deposition. Reference numeral 309 represents metal gate electrodes formed of TiN, Ti, Ta, TaN or a combination two or more thereof. Reference numeral 310 represents a dielectric layer of SiO₂. Dotted lines 401 represent a depth of a bottom of shallow trench isolation structure regions. Dotted lines 402, 403, and 404 represent depth of formed P-N junctions.

Detailed discussions regarding the fabrication processes for forming the P-type vertical MOS field-effect-transistor DRAM array devices is omitted here because they are similar to those for forming the N-type vertical MOS field-effect-transistor DRAM array devices. After forming the capacitors coupled to the heavily doped P-type regions in the vertical MOS field-effect-transistor array devices shown in FIG. 13, a DRAM array could be formed (illustration omitted). Compared to the N-type vertical MOS field-effect-transistors, P-type vertical MOS field-effect-transistors have smaller transient bipolar gain. By design optimization, this gain can be smaller than 1. Thus, the P-type vertical MOS field-effect-transistors are more advantageous at avoiding the problem of floating body effect that can be associated with vertical DRAM array devices lacking contact with body silicon.

As discussed above, without departing from the spirit and scope of the present invention, various largely different embodiments can be formed. It is to be understood that, except what is defined by the appended claims, the present invention is not limited by the specific embodiments described in the specification.

1. A method of making a DRAM array, the method comprising:
forming, for each of a plurality of vertical MOS field-effect-transistor array devices, a first highly doped region near a surface of a semiconductor substrate;
etching the semiconductor substrate to form openings;
covering sidewalls of the openings with an insulating film;
implanting dopant ions into the openings and activating the dopant ions to form second highly doped regions near bottoms of the openings;
depositing a first metal layer over the semiconductor substrate, the first metal layer covering the sidewalls and bottoms of the openings;
causing the first metal layer to react with the semiconductor substrate near bottoms of the openings to form metal silicide in the second highly doped regions, whereby metal silicide in each opening expands to join metal silicide in neighboring openings to form contiguous bit lines connecting respective sets of multiple consecutive vertical MOS field-effect-transistor array devices; and
forming, for the each of the plurality of vertical MOS field-effect-transistor array devices, buried metal double gate structures, the buried metal double gate structures acting as word lines for the DRAM array.

2. The method of claim 1, wherein the method further comprises anisotropically etching the semiconductor substrate after covering the sidewalls of the openings with the insulating film and before depositing the first metal layer to reduce widths of portions of the semiconductor substrate between the openings, thereby allowing the metal silicide in each opening to expand to join metal silicide in neighboring openings to form the contiguous bit lines.

3. The method according to claim 1, wherein the buried metal double gate structures are formed on sidewalls of the openings.

4. The method according to claim 1, wherein covering the sidewalls of the openings is performed after the second highly doped regions are formed.

5. The method according to claim 1, wherein covering the sidewalls of the openings comprises:
forming an etch mask layer; and
anisotropically etching the etch mask layer to expose areas of silicon for forming the metal silicide;
wherein the etch mask layer includes SiO2, Si₃N₄, or a combination thereof.

6. The method according to claim 1, wherein the metal silicide is selected from the group consisting of titanium silicide, cobalt silicide, nickel silicide, platinum silicide, and combinations thereof.

7. The method according to claim 1, further comprising, after forming the contiguous bit lines and before forming the buried metal double gate structures:
forming an insulating dielectric layer; and
dry etching the insulating dielectric layer, retaining portions of the insulating dielectric layer near bottoms of the openings.

8. The method according to claim 1, wherein forming the buried metal double gate structures comprises:
forming a gate insulator layer on the sidewalls of the openings; and
depositing a second metal layer over the gate insulator layer; and
anisotropically etching the second metal layer to form metal gate electrodes on the gate insulator layer.

9. A method of making a DRAM array, the method comprising:
forming shallow trench isolation structures in a semiconductor substrate, each of the shallow trench isolation structures extending along a first direction across the semiconductor substrate;
forming first highly doped region near the surface of the semiconductor substrate;
forming a mask layer over the semiconductor substrate, the mask layer being patterned to define openings extending along a second direction across the semiconductor substrate, the second direction being perpendicular to the first direction;
etching the semiconductor substrate through the openings of the mask layer to form openings in the semiconductor substrate;
covering sidewalls of the openings in the semiconductor substrate with an insulating film;
implanting dopant ions into the openings of the semiconductor substrate and activating the dopant ions to form second highly doped regions near bottoms of the openings;
forming buried metal silicide bit lines in the second highly-doped regions; and
forming buried metal double gate structures on the sidewalls of the openings in the semiconductor substrate, the buried metal double gate structures acting as word lines for the DRAM array.

10. The method of claim 9, wherein forming buried metal silicide bit lines in the second highly-doped regions comprises:
depositing a first metal layer, the first metal layer covering sidewalls and bottoms of the openings in the semiconductor substrate;
causing the first metal layer to react with the semiconductor substrate to form metal silicide near bottoms of the openings in the semiconductor substrate, the metal silicide in neighboring openings in the semiconductor substrate expanding to join each other, thereby forming the buried metal silicide bit lines extending along the first direction; and
removing unreacted metal in the first metal layer.

11. The method of claim 10, wherein the method further comprises anisotropically etching the semiconductor substrate after covering the sidewalls of the openings in the semiconductor substrate with the insulating film and before depositing the first metal layer to reduce widths of portions of the semiconductor substrate between the openings in the semiconductor substrate, thereby allowing the metal silicide in each opening to expend to join metal silicide in neighboring openings to form contiguous bit lines.

12. The method according to claim 9, wherein covering the sidewalls of the openings in the semiconductor substrate comprises:
forming an etch mask layer; and
anisotropically etching the etch mask layer to expose areas of silicon for forming the buried metal silicide bit lines;
wherein the etch mask layer includes SiO2, Si₃N₄, or a combination thereof.

13. The method according to claim 9, further comprising, after forming the buried metal silicide bit lines and before forming the buried double gate structures:
forming an insulating dielectric layer; and
dry etching the insulating dielectric layer, retaining portions of the insulating dielectric layer near bottoms of the openings.

14. The method according to claim 9, wherein forming the buried metal double gate structures comprises:
forming a gate insulator layer on the sidewalls of the openings; and
depositing a second metal layer over the gate insulator layer; and
anisotropically etching the second metal layer to form metal gate electrodes on the gate insulator layer.

15. A method of making a DRAM array, the method comprising:
forming, for each of a plurality of vertical MOS field-effect-transistor array devices, a first highly doped region near a surface of a semiconductor substrate;
etching the semiconductor substrate to form openings;
covering sidewalls of the openings with an insulating film;
forming second highly doped regions near bottoms of the openings;
anisotropically etching the semiconductor substrate to reduce widths of portions of the semiconductor substrate between the openings and near bottoms of the openings;
depositing a first metal layer over the semiconductor substrate;
causing the first metal layer to react with the semiconductor substrate near bottoms of the openings to form metal silicide in the second highly doped regions, whereby metal silicide in each opening expands to join metal silicide in neighboring openings to form contiguous bit lines connecting respective sets of multiple consecutive vertical MOS field-effect-transistor array devices; and
forming, for the each of the plurality of vertical MOS field-effect-transistor array devices, buried metal double gate structures, the buried metal double gate structures acting as word lines for the DRAM array.

16. The method of claim 15, further comprising:
removing unreacted metal in the first metal layer.

17. The method according to claim 15, wherein covering the sidewalls of the openings in the semiconductor substrate comprises:
forming an etch mask layer; and
anisotropically etching the etch mask layer to expose areas of silicon for forming the metal silicide;
wherein the etch mask layer includes SiO2, Si₃N₄, or a combination thereof.

18. The method according to claim 15, further comprising, after forming the contiguous bit lines and before forming the buried metal double gate structures:
forming an insulating dielectric layer; and
dry etching the insulating dielectric layer, retaining portions of the insulating dielectric layer near bottoms of the openings.

19. The method according to claim 15, wherein forming the buried metal double gate structures comprises:
forming a gate insulator layer on the sidewalls of the openings; and
depositing a second metal layer over the gate insulator layer; and
anisotropically etching the second metal layer to form metal gate electrodes on the gate insulator layer.
